(19) United States
(12) Patent Application Publication
(10) Pub. No.: US 2024/0178124 A1
(43) Pub. Date: May 30, 2024

(54) Embedded Die Package

(71) Applicant: Compass Technology Company Limited, Shatin Hong Kong (CN)

(72) Inventors: Kelvin Po Leung Pun, Hong Kong SAR (CN); Chee Wah Cheung, Hong Kong SAR (CN); Jason Rotanson, Hong Kong SAR (CN)

(21) Appl. No.: 18/071,819

(22) Filed: Nov. 30, 2022

(51) Int. Cl. H01L 23/498; H01L 21/56; H01L 23/00; H01L 23/31

(52) U.S. Cl. CPC H01L 23/4985; H01L 21/56; H01L 23/3121; H01L 24/32; H01L 24/83; H01L 24/08; H01L 2224/08225; H01L 2224/32225; H01L 2224/838

(57) ABSTRACT

A flexible substrate embedded die package is described comprising a multi-layer flexible substrate comprising a dielectric substrate, a top metal layer and a bottom metal layer connected with micro-via interconnection through said dielectric substrate, a semiconductor die attached by an adhesive to the flexible substrate and a dielectric bonding film surrounding the semiconductor die and sealing the semiconductor die to the flexible substrate.

### TECHNICAL FIELD

This application relates to producing a flexible substrate for integrated circuit packaging, and more particularly, to producing a flexible substrate embedded die package.

### BACKGROUND

Conventionally, integrated circuit (IC) dies are packaged by situating the component on top of a substrate, which is then interconnected by a flip-chip or wire bonding method. The substrate acts as an interposer between the device and the main board. Embedded die is an IC packaging type in which components such as a die, multiple dies, passives, or Micro-Electro-Mechanical Systems (MEMS) are directly embedded into a substrate without any additional interconnection. This method offers significant size miniaturization of the device package and thus allow for more design flexibility. Furthermore, it also enhances die interconnection reliability, device performance, and improved protection as the component is completely sealed inside the substrate. For these reasons, this technology attracts lots of attention especially from automotive and datacenter industries where high power and thermal management are required along with size miniaturization. However, embedded die technology also faces many challenges due to manufacturing yield and supply chain maturity issues. Prior to integrating the die onto the substrate, embedding the die typically requires additional processing at the wafer level (before it is diced/singulated) or at the panel level. These additional processes not only lead to increased cost but also to supply chain ownership issues.

Flexible electronics have emerged as promising solutions for device miniaturization as they provide numerous advantages including higher circuit density, thinner profile, lighter weight, and shape conformance capability (foldable and bendable) as compared to their rigid counterpart of printed circuit board (PCB). In terms of processing, flexible electronics also offer competitive cost and efficiency due to their reel-to-reel manufacturing capability.

Embedding components on a flexible substrate is an attractive packaging solution to provide a combination of increased input/output (I/O) density, size miniaturization, improved electrical and thermal performance, heterogeneous integration, and reel-to-reel processing capability. In a conventional package, typically passive components cannot be placed near the active component (semiconductor die) due to heat dissipation issues. By embedding the die on the substrate beforehand, passive components can also be assembled on top of the die itself, thus minimizing the device footprint on the package.

U.S. Pat. No. 8,780,335 (Van Steenberge et al) and U.S. Pat. No. 7,803,658 (Shimanuki) and U.S. Patent Applications 2016/0056101 (Jee et al), 2019/0333895 (Kim), 3030/0185322 (Zhang et al), and 2016/0233166 (Teh et al) teach various semiconductor die packages.

### SUMMARY

A principal object of the present disclosure is to provide a flexible substrate embedded die package.

Another object of the present disclosure is to provide a flexible substrate embedded die package that has reduced thickness, hermetic sealing, and dielectric strength.

A further object is to provide a flexible substrate embedded die package without through silicon vias.

A still further object is to provide a method of producing a flexible substrate embedded die package.

According to the objects of the disclosure, a flexible substrate embedded die package is achieved. The flexible substrate embedded die package comprises a multi-layer flexible substrate comprising a dielectric substrate, a top metal layer and a bottom metal layer connected with micro-via interconnection through the dielectric substrate, a semiconductor die attached by an adhesive to the flexible substrate and a dielectric bonding film surrounding the semiconductor die and sealing the semiconductor die to the flexible substrate

Also according to the objects of the disclosure, a method to produce a flexible substrate embedded die package is achieved. A multi-layer flexible substrate is provided comprising a dielectric substrate, a top metal layer and a bottom metal layer connected with micro-via interconnection through the dielectric substrate. A semiconductor die is die attached to the flexible substrate by an adhesive. A dielectric bonding film is laminated onto the flexible substrate and the semiconductor die and cured to seal the semiconductor die to the flexible substrate.

Also according to the objects of the disclosure, a flexible substrate embedded die package is achieved. The flexible substrate embedded die package comprises a multi-layer flexible substrate comprising a dielectric substrate, a top metal layer and a bottom metal layer connected with micro-via interconnection through the dielectric substrate, a first semiconductor die attached by an adhesive to the top metal layer of the flexible substrate, a second semiconductor die attached by an adhesive to the bottom metal layer of the flexible substrate, and a dielectric bonding film surrounding the first and second semiconductor dies and sealing them to the flexible substrate.

Also according to the objects of the disclosure, a flexible substrate embedded die package is achieved. The flexible substrate embedded die package comprises a first multi-layer flexible substrate comprising a first dielectric substrate, a first top metal layer and a first bottom metal layer connected with first micro-via interconnection through the first dielectric substrate, a semiconductor die attached by an adhesive to the first flexible substrate, a dielectric bonding film surrounding the semiconductor die and sealing the semiconductor die to the first flexible substrate, circuitry on top of the dielectric bonding film to fan out internal circuitry of the semiconductor die onto the first flexible substrate, and a second multi-layer flexible substrate comprising a second dielectric substrate, a second top metal layer and a second bottom metal layer connected with second micro-via interconnection through the second dielectric substrate and another layer of dielectric bonding film to the first multi-layer flexible substrate with second micro-via interconnection through the second dielectric substrate.

### BRIEF DESCRIPTION OF THE DRAWINGS

In the accompanying drawings forming a material part of this description, there is shown:

FIG. 1 is a cross-sectional representation of a flexible substrate embedded die package in a first preferred embodiment of the present disclosure.

FIGS. 2-6 schematically illustrate in cross-sectional representation steps in a process to fabricate the flexible substrate embedded die package of the first preferred embodiment of the present disclosure.

FIG. 7 is a cross-sectional representation of a completed flexible substrate embedded die package in the first preferred embodiment of the present disclosure.

FIG. 8 is a cross-sectional representation of a double-sided flexible substrate embedded die package in a second preferred embodiment of the present disclosure.

FIG. 9 is a cross-sectional representation of a flexible substrate embedded die package with an additional multi-layer flexible substrate in a third preferred embodiment of the present disclosure.

### DESCRIPTION OF THE PREFERRED EMBODIMENTS

The flexible substrate embedded die package of the present disclosure is made with an adhesive interconnect, low temperature, and pressure bonding to handle the thin and fragile die structure without damaging internal die structure. A package thickness of less than about 100 μm can be achieved.

FIG. 1 is a cross-sectional illustration of a sample flexible substrate embedded die package of the present disclosure. A multi-layer flexible substrate preferably has two metal layers with top 14 and bottom 12 metal layers connected with micro-via interconnection 16 through the dielectric substrate layer 10. The dielectric substrate thickness ranges from about 5 to 25 μm, the top metal layer thickness ranges from 1-10 μm, and the bottom metal thickness ranges from 1-10 μm, for a total substrate thickness of between about 10 to 45 μm. A semiconductor die 20 is die attached by an adhesive 26 to the flexible substrate. Preferably the adhesive is an anisotropic conductive film (ACF), an anisotropic conductive paste (ACP), a non-conductive film (NCF), or a non-conductive paste (NCP). A dielectric bonding film 30 surrounds the die and seals it to the flexible substrate. Circuitry 34/38 is formed on top of the bonding film 30 to fan out the die internal circuitry onto the flexible substrate. The bottom metal layer 12 of the substrate can be mounted on a printed circuit board (PCB) 50 by solder balls 40, for example.

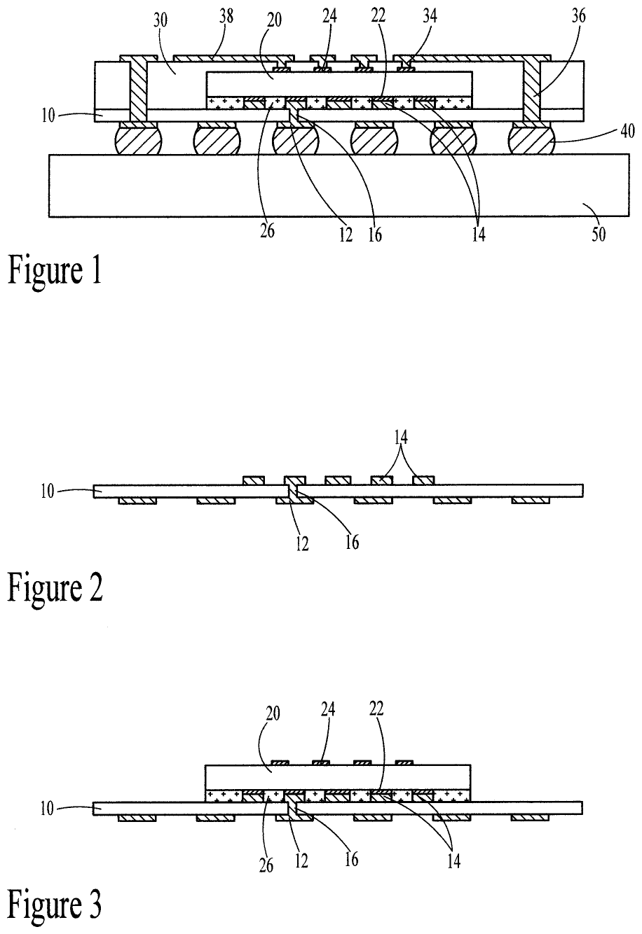

A fabrication process for the flexible substrate embedded die package of the present disclosure will be described with reference to FIGS. 2-6. Referring now more particularly to FIG. 2, the flexible substrate comprises a dielecric base film 10 such as polyimide (PI), liquid crystal polymer (LCP), Polyester (PET), polyethylene-naphthalate (PEN), cyclo-olefin polymer (COP), poly tetra fluoro ethylene, or a laminate substrate comprising epoxies and Bismaleimide-Triazine (BT), or Teflon or modified Teflon, Syndiotactic Polystyrene (SPS), or Bis Malelmide (BMI), for example. Metal circuitry, preferably copper, is provided on bottom 12 and top 14 of the flexible substrate, including interconnections 16 between top and bottom metal layers.

Now a semiconductor die 20 is fabricated. In this case, metal circuitry has been formed on bottom 22 and top 24 surfaces of the die as well as internally to the die, not shown. The die wafer can further be grinded to achieve a thickness of 25-75 μm. The grinding can both reduce the thickness of the final package and provide stress relief.

The die 20 is die attached to the flexible substrate 10, as shown in FIG. 3. Metal pads 22 on the bottom of the die attach to metal pads 14 on the top of the substrate. The die attach is by thermo-compression bonding with a conductive or non-conductive film 26. Preferably, this film 26 is an anisotropic conductive film (ACF), an anisotropic conductive paste (ACP), a non-conductive film (NCF), or a non-conductive paste (NCP). Using this type of adhesive interconnect allows a low temperature and low pressure bonding which will not damage the internal die structure of the thin and fragile die. The adhesive line 26 can be very thin, less than about 5 μm for package size reduction. Preferably, the temperature range is from about 130 to 230° C. and pressure is between about 120 and 280 MPa.

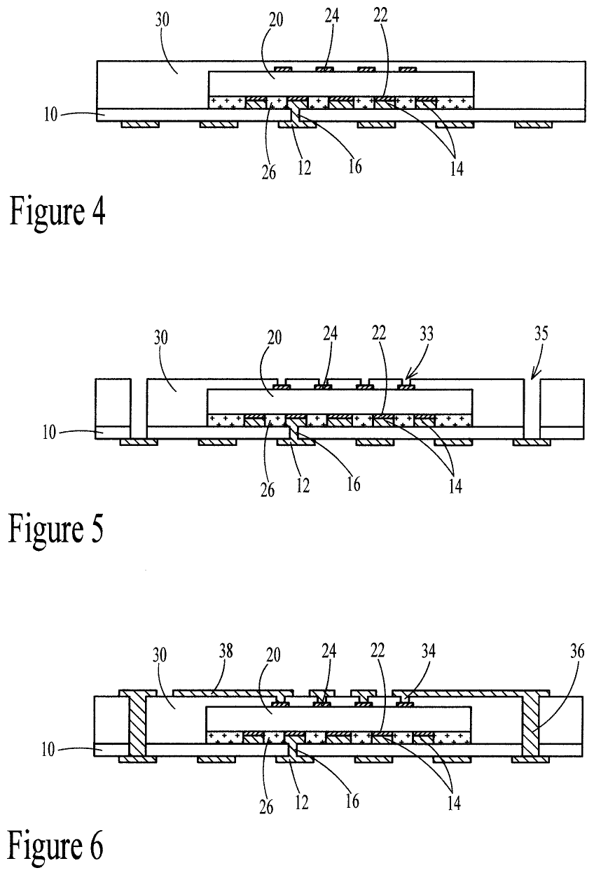

Now, as illustrated in FIG. 4, a bonding film 30 is laminated on top of the die 20 and flexible substrate 10 in a hot press process. The bonding film can be any kind of dielectric material including polyimide, fluoropolymer, polyester, and so on. The bonding material can be any kind of modified epoxy or thermoset adhesive film such as epoxy, cyanide ester, or acrylic adhesive, reinforced with fibers. The bonding film will have a high glass transition temperature (Tg) of between about 120 and 170° C. and a low coefficient of thermal expansion (CTE) of between about 10 and 50 at a temperature below Tg and a CTE of between about 70 and 200 at a temperature above Tg. Alternatively, the bonding film can be an Ajinomoto Bonding film (ABF), an epoxy resin-based film consisting of: Bisphenol A epoxy resin: 9 wt. %, Petroleum naphtha: under 5.0 wt. %, Cyclohexanone: 1.1 wt. %, N, N-dimethylformamide: 0.5 wt. %, Toluene: under 5.0 wt. %, Ethanol: under 5.0 wt. %, Methyl ethyl ketone: under 5.0 wt. %, and Silica powder: 30″40 wt. %. Alternatively, the bonding film can be Dupont FR0100 bonding film made of modified acrylic: N, N′-ethylenebis:>=10-<20%, and Antimoney trioxide:>=1-<10%. The bonding film may be deposited as multiple layers.

Next, the bonding film 30 is cured at a temperature above its Tg (glass transition temperature) which changes the bonding film to be viscous and rubbery. During this glass-liquid transition state, the bonding film's shape conforms to the die shape. After curing, the bonding film returns to a solid; thus the die is completely protected and hermetically sealed, providing excellent dielectric strength and package thickness reduction.

Referring now to FIG. 5, laser micro-via drilling 33 on the bonding film above the die is performed to expose the metal pads 24 on the die top surface. Additional micro0vias 35 can be formed through the bonding film to the bottom metallization 12 on the flexible substrate. Via metallization 34 and 36 is followed by copper plating 38 to fill the micro-vias as signal paths to the die 20 and as fan out circuitry from the internal circuitry of the die. Both compact top and bottom circuitry of the die can be fanned out to the substrate, as shown in FIG. 6, eliminating the need of through silicon vias (TSV) through the silicon die 20.

Finally, as shown in FIG. 1, the bottom metal layer 12 of the substrate can be mounted on a printed circuit board (PCB) 50 by soldering or conductive ink. Total substrate package size, not including the PCB, can range from between about 60 to 150 μm. For example, using a 12.5 μm flexible substrate and a 50 μm thick die, the overall package thickness can be <100 μm. With the thin package size, the package fabrication can be done in a reel-to-reel process to improve registration tolerance, repeatability, and throughput.

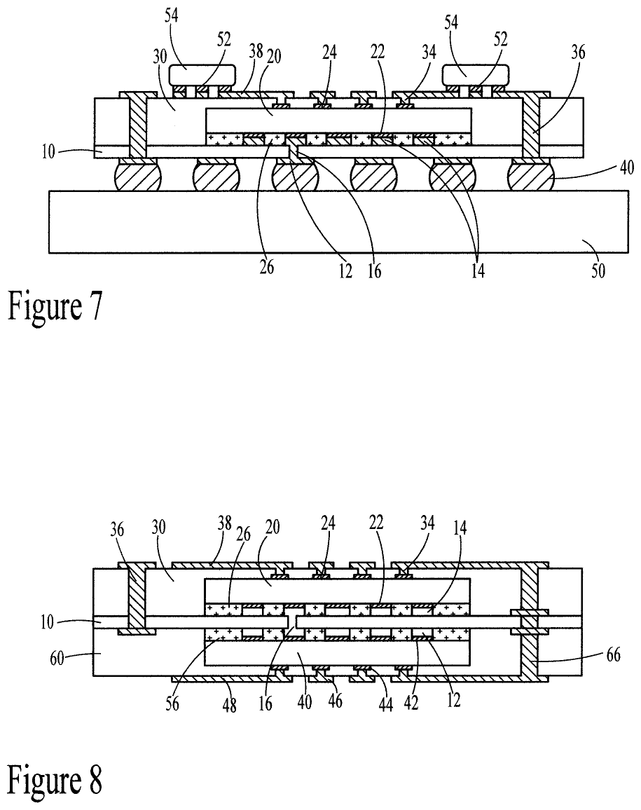

Furthermore, as shown in FIG. 7, passive components may be mounted on the top metal layer 38. Passive components 54 may be resistors, capacitors, or inductors, for example, and may be mounted by surface mount technology 52, such as by soldering. By embedding the die on the substrate beforehand, passive components 54 can also be assembled directly over the die itself, thus minimizing the device footprint on the package.

The flexible substrate embedded die package of the present disclosure can be used for high power and high reliability applications such as automotive electronics (radar sensor, lidar sensor, camera modules, ultrasonic sensing, communication system, power converters, motor control units, and lighting modules) and data center (RF power management, servers, and CPUs) applications.

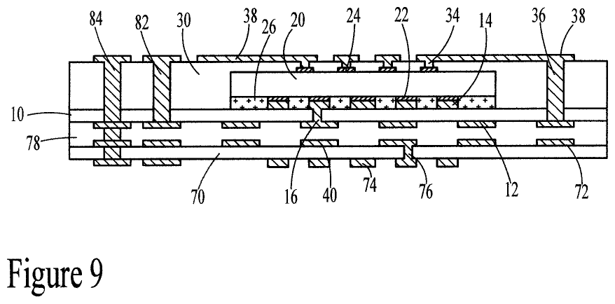

FIGS. 8 and 9 illustrate additional flexible substrate embedded die packages according to the present disclosure. FIG. 8 illustrates a double-sided assembly where a first die 20 is die attached by adhesive 26 to a first side of flexible substrate 12/10/14 and a second die 40 is die attached by adhesive 56 to the opposite side of flexible substrate 12/10/14. Dielectric bonding film 30 surrounds the first die 20 and seals it to the flexible substrate. Dielectric bonding film 60 surrounds the second die 40 and seals it to the flexible substrate. Circuitry 34/38 is formed on top of the bonding film 30 to fan out the die 20 internal circuitry onto the flexible substrate. Circuitry 46/48 is formed on top of the bonding film 60 to fan out the die 40 internal circuitry onto the flexible substrate. Metal via 66 provides a signal path from top to bottom of the package. The top metal layer 12 or the bottom metal layer 48 of the package could be mounted on a printed circuit board (PCB), not shown, and passive components may be mounted on either of both of the top metal layers 12/48, as shown in FIG. 7 for the first embodiment.

FIG. 9 illustrates a package with a flexible substrate embedded die with an additional multi-layer flexible substrate. Die 20 is die attached by adhesive 26 to a flexible substrate 12/10/14. Dielectric bonding film 30 surrounds the die 20 and seals it to the flexible substrate. Circuitry 34/38 is formed on top of the bonding film 30 to fan out the die 20 internal circuitry onto the flexible substrate. A second flexible substrate 70 has top metal layer 72 and bottom metal layer 74 connected by filled vias 76. Dielectric bonding film 78 joins the first substrate 10 to the second substrate 70. Metal filled micro-vias connect various combinations of metal layers. For example, as shown in FIG. 9, via 36 connects metal layers 12 and 38. Via 76 connects layers 72 and 74 of the second flexible substrate. Via 16 connects layers 12 and 14 of the first flexible substrate. Via 82 connects layers 38, 12, and 72, and via 84 connects layers 38, 12, 72, and 74.

Although the preferred embodiment of the present disclosure has been illustrated, and that form has been described in detail, it will be readily understood by those skilled in the art that various modifications may be made therein without departing from the spirit of the disclosure or from the scope of the appended claims.

What is claimed is:

1. A flexible substrate embedded die package comprising:
a multi-layer flexible substrate comprising a dielectric substrate, a top metal layer and a bottom metal layer connected with micro-via interconnection through said dielectric substrate;
a semiconductor die attached by an adhesive to said flexible substrate; and
a dielectric bonding film surrounding said semiconductor die and sealing said semiconductor die to said flexible substrate.

2. The package according to claim 1 wherein said dielectric substrate comprises polyimide (PI), liquid crystal polymer (LCP), Polyester (PET), polyethylene-naphthalate (PEN), cyclo-olefin polymer (COP), poly tetra fluoro ethylene, or a laminate substrate comprising epoxies and BT, or Teflon or modified Teflon, Syndiotactic Polystyrene (SPS), or Bis Malelmide (BMI).

3. The package according to claim 1 wherein said flexible substrate has a thickness of between about 10 and 45 μm.

4. The package according to claim 1 wherein said adhesive comprises an anisotropic conductive film (ACF), an anisotropic conductive paste (ACP), a non-conductive film (NCF), or a non-conductive paste (NCP).

5. The package according to claim 1 wherein said dielectric bonding film comprises polyimide, fluoropolymer, polyester. modified epoxy, or thermoset adhesive film reinforced with fibers, such as epoxy, cyanide ester, or acrylic adhesive.

6. The package according to claim 1 wherein said dielectric bonding film has a glass transition temperature of between about 120 and 170° C. and a coefficient of thermal expansion of between about 10 and 50 at a temperature below the glass transition temperature and between about 70 and 200 at a temperature above the glass transition temperature.

7. The package according to claim 1 further comprising circuitry on top of said dielectric bonding film to fan out internal circuitry of said semiconductor die onto said flexible substrate.

8. The package according to claim 1 further comprising a printed circuit board mounted onto said bottom metal layer.

9. The package according to claim 1 wherein said package has a thickness of less than about 100 μm.

10. The package according to claim 1 further comprising at least one passive component mounted on said top metal layer.

11. A method for fabricating a flexible substrate embedded die package comprising:
providing a multi-layer flexible substrate comprising a dielectric substrate, a top metal layer and a bottom metal layer connected with micro-via interconnection through said dielectric substrate;
die attaching a semiconductor die by an adhesive to said flexible substrate;
laminating a dielectric bonding film onto said flexible substrate and said semiconductor die; and
curing said dielectric bonding film to seal said semiconductor die to said flexible substrate.

12. The method according to claim 11 wherein said dielectric substrate comprises polyimide (PI), liquid crystal polymer (LCP), Polyester (PET), polyethylene-naphthalate (PEN), cyclo-olefin polymer (COP), poly tetra fluoro ethylene, or a laminate substrate comprising epoxies and BT, or Teflon or modified Teflon, Syndiotactic Polystyrene (SPS), or Bis Malelmide (BMI).

13. The method according to claim 11 wherein said flexible substrate has a thickness of between about 10 and 45 μm.

14. The method according to claim 11 wherein said die attaching comprises thermo-compression bonding at a temperature of between about 130 and 230° C. and pressure of between about 120- and 280 mPa using said adhesive comprising an anisotropic conductive film (ACF), an anisotropic conductive paste (ACP), a non-conductive film (NCF), or a non-conductive paste (NCP).

15. The method according to claim 11 wherein said dielectric bonding film comprises polyimide, fluoropolymer, polyester. modified epoxy, or thermoset adhesive film reinforced with fibers, such as epoxy, cyanide ester, or acrylic adhesive.

16. The method according to claim 11 wherein said dielectric bonding film has a glass transition temperature of between about 120 and 170° C. and a coefficient of thermal expansion of between about 10 and 50 at a temperature below the glass transition temperature and between about 70 and 200 at a temperature above the glass transition temperature.

17. The method according to claim 11 wherein said curing said dielectric bonding film comprises curing at a temperature above its glass transition temperature.

18. The method according to claim 11 further comprising:
laser drilling first micro-vias through cured said bonding film to metal pads on a top surface of said semiconductor substrate;
laser drilling second micro-vias through cured said bonding film to said bottom metal layer of said flexible substrate;
filling said first and second micro-vias with metal; and
forming circuitry on said metal in said first and second micro-vias to fan out internal circuitry of said semiconductor die onto said flexible substrate.

19. The method according to claim 11 further comprising:
mounting a printed circuit board onto said bottom metal layer.

20. The method according to claim 19 wherein said mounting comprises soldering or using conductive ink.

21. The method according to claim 11 wherein said package has a thickness of less than about 100 μm.

22. The method according to claim 11 further comprising:
mounting at least one passive component onto said top metal layer.

23. A flexible substrate embedded die package comprising:
a multi-layer flexible substrate comprising a dielectric substrate, a top metal layer and a bottom metal layer connected with micro-via interconnection through said dielectric substrate;
a first semiconductor die attached by an adhesive to said top metal layer of said flexible substrate;
a second semiconductor die attached by an adhesive to said bottom metal layer of said flexible substrate; and
a dielectric bonding film surrounding said first and second semiconductor dies and sealing said first and second semiconductor dies to said flexible substrate.

24. A flexible substrate embedded die package comprising:
a first multi-layer flexible substrate comprising a first dielectric substrate, a first top metal layer and a first bottom metal layer connected with first micro-via interconnection through said first dielectric substrate;
a semiconductor die attached by an adhesive to said first flexible substrate;
a first dielectric bonding film surrounding said semiconductor die and sealing said semiconductor die to said first flexible substrate;
circuitry on top of said dielectric bonding film to fan out internal circuitry of said semiconductor die onto said first flexible substrate; and
a second multi-layer flexible substrate comprising a second dielectric substrate, a second top metal layer and a second bottom metal layer connected with second micro-via interconnection through said second dielectric substrate and attached by a second dielectric bonding film to said first multi-layer flexible substrate with second micro-via interconnection through said second dielectric substrate.

25. The package according to claim 24 further comprising:
a third micro-via interconnection between said circuitry and said first top metal layer through said dielectric bonding film and said first dielectric substrate.

26. The package according to claim 24 further comprising:
a fourth micro-via interconnection between said circuitry, said first bottom metal layer, and said second top metal layer through said dielectric bonding film, said first dielectric substrate, and said second bottom metal layer.

27. The package according to claim 24 further comprising:
a fifth micro-via interconnection between said circuitry, said first bottom metal layer, said second top metal layer, and said second bottom metal layer through said first dielectric bonding film, said first dielectric substrate, said second dielectric bonding film, and said second dielectric substrate.
